(19) United States
(12) Patent Application Publication
(10) Pub. No.: US 2023/0021526 A1
(43) Pub. Date: Jan. 26, 2023

(54) DRIVER CIRCUIT FOR AN ADDRESSABLE ARRAY OF OPTICAL EMITTERS

(71) Applicant: Lumentum Operations LLC, San Jose, CA (US)

(72) Inventors: Mikhail DOLGANOV, Gilroy, CA (US); Lijun ZHU, Pleasanton, CA (US)

(21) Appl. No.: 17/643,712

(22) Filed: Dec. 10, 2021

Related U.S. Application Data
(60) Provisional application No. 63/203,426, filed on Jul. 22, 2021.

(51) Int. Cl. G01S 7/4865; G01S 17/08

(52) U.S. Cl. CPC G01S 7/4865; G01S 17/08

(57) ABSTRACT

A driver circuit may include an array of optical emitters arranged in one or more rows and one or more columns. The array of optical emitters includes an optical emitter associated with a row and a column. The driver circuit may include a capacitive element connected to the row, a voltage booster element connected to the capacitive element, where the voltage booster element includes an inductive element, and a first switch having an open state and a closed state. The first switch in the closed state is to cause charging of the inductive element, and in the open state is to cause discharging of the inductive element to charge the capacitive element. The driver circuit may include a second switch having an open state and a closed state. The second switch in the closed state is to cause discharging of the capacitive element through the row and the column.

### CROSS-REFERENCE TO RELATED APPLICATION

This patent application claims priority to U.S. Provisional Patent Application No. 63/203,426, filed on Jul. 22, 2021, and entitled “DRIVER CIRCUIT FOR AN ADDRESSABLE ARRAY OF OPTICAL EMITTERS.” The disclosure of the prior application is considered part of and is incorporated by reference into this patent application.

### TECHNICAL FIELD

The present disclosure relates generally to an addressable array of optical emitters and to a driver circuit for an addressable array of optical emitters.

### BACKGROUND

Light detection and ranging (LIDAR) systems, such as time-of-flight (ToF)-based measurement systems, emit optical pulses, detect reflected optical pulses, and determine distances to objects by measuring delays between the emitted optical pulses and the reflected optical pulses.

### SUMMARY

In some implementations, a driver circuit includes an array of optical emitters arranged in one or more rows and one or more columns, where the array of optical emitters includes an optical emitter associated with a row of the one or more rows and a column of the one or more columns; a capacitive element connected to the row; a voltage booster element connected to the capacitive element, where the voltage booster element includes an inductive element; a first switch having an open state and a closed state, where the first switch in the closed state is to cause charging of the inductive element, and where the first switch transitioning from the closed state to the open state is to cause discharging of the inductive element to charge the capacitive element; and a second switch having an open state and a closed state, where the second switch in the closed state is to select the column, and where the second switch in the closed state is to cause discharging of the capacitive element through the row and the column to provide an electrical pulse to the optical emitter associated with the row and the column.

In some implementations, a controller for an array of optical emitters arranged in a plurality of rows and a plurality of columns includes a plurality of capacitive elements respectively connected to the plurality of rows; a plurality of inductive elements respectively connected to the plurality of capacitive elements; a plurality of first switches respectively connected to the plurality of inductive elements, where the plurality of first switches have an open state and a closed state, where a first switch, of the plurality of first switches, in the closed state is to cause charging of an inductive element of the plurality of inductive elements, and where the first switch transitioning from the closed state to the open state is to cause discharging of the inductive element to charge a capacitive element, of the plurality of capacitive elements, for a row of the plurality of rows; and a plurality of second switches respectively connected to the plurality of columns, where the plurality of second switches have an open state and a closed state, and where a second switch, of the plurality of second switches, connected to a column of the plurality of columns, in the closed state is to cause discharging of the capacitive element through the row and the column.

In some implementations, a method includes causing, by a device and using a first switch, charging of an inductive element for a first duration; causing, by the device and using the first switch, discharging of the inductive element to charge a capacitive element, where the capacitive element is connected to a row of an array of optical emitters; and causing, by the device and using a second switch connected to a column of the array of optical emitters, discharging of the capacitive element, to an optical emitter associated with the row and the column, for a second duration.

### BRIEF DESCRIPTION OF THE DRAWINGS

FIG. 1 is a diagram of an example driver circuit described herein.

FIG. 2 is a diagram of an example graph plotting electrical signals associated with an example driver circuit described herein.

FIG. 3 is a flowchart of an example process associated with controlling a driver circuit for an addressable array of optical emitters described herein.

### DETAILED DESCRIPTION

The following detailed description of example implementations refers to the accompanying drawings. The same reference numbers in different drawings may identify the same or similar elements.

LIDAR systems, such as ToF-based measurement systems (e.g., direct ToF LIDAR systems), require high power optical pulses of short duration (e.g., 10 nanoseconds (ns) or less). High power optical pulses may enable greater distance range finding. Shorter duration optical pulses may enable improved resolution. For a laser-based optical load (e.g., a laser diode, a semiconductor laser diode, a vertical-cavity surface-emitting laser (VCSEL), or the like), a higher electrical current across the optical load corresponds to a higher power optical pulse. As noted, ToF-based measurement systems may determine distances to objects by measuring delays between an emitted optical pulse and a reflected optical pulse. Emitting pulses having a well-defined origin in time and a Gaussian shape simplifies the measurements. To achieve such a Gaussian shape, emitted optical pulses should have short rise times (e.g., a time during which power of the optical pulse is rising from zero or near zero to peak power) and short fall times (e.g., a time during which power of the optical pulse is falling from peak power to zero or near zero).

A circuit for driving an optical load is a set of electronic components interconnected by current-carrying conductors (e.g., traces). Any of the electronic components and conductors may have parasitic elements (e.g., a parasitic inductance, a parasitic resistance, and/or a parasitic capacitance). For example, the traces in an array (e.g., a matrix) of optical emitters may be long, thereby resulting in high parasitic inductances. Moreover, current paths, via the traces, for different optical emitters (e.g., different pixels) of the array may have different lengths. Thus, the current paths for the different optical emitters may be associated with different parasitic inductance values. As a result, current pulse amplitudes and/or pulse widths may be different for different optical emitters of the array, which may adversely affect ToF-based measurement.

Some implementations described herein provide a driver circuit for an array of optical emitters. The driver circuit provides addressability of individual emitters of the array. Moreover, the driver circuit may enable adjustment (e.g., in real-time) of peak current pulse amplitudes and pulse widths at different locations (e.g., at different emitters) in the array. Furthermore, the driver circuit is capable of producing Gaussian-shaped optical pulses with fast rise times.

In some implementations, the driver circuit includes an array of optical emitters arranged in one or more rows and one or more columns. The driver circuit may include respective capacitive elements connected to each row of the array of optical emitters (e.g., thereby enabling a particular row to be addressed). The driver circuit may include respective inductive elements (e.g., associated with respective voltage booster elements) connected to the capacitive elements. An inductive element may be configured to charge a capacitive element to a particular voltage according to a charging time of the inductive element. In this way, by adjusting (e.g., in real time) respective charging times of the inductive elements, the capacitive elements may be charged to respective voltages based on desired optical pulse amplitudes for optical emitters of the array. For example, the charging times may be based on current path lengths associated with different optical emitters of the array. The driver circuit may also include respective switches associated with each column of the array of optical emitters. These switches may control discharging of the capacitive elements. Thus, by adjusting (e.g., in real time) respective discharging times of the capacitive elements (e.g., based on a duration in which the switches are in a closed state), a desired pulse width may be achieved for optical emitters of the array. For example, the discharging times may be based on locations of optical emitters of the array. In this way, the driver circuit may compensate for different parasitic inductances associated with different optical emitters of the array, thereby improving a uniformity of optical pulses produced by the array of optical emitters.

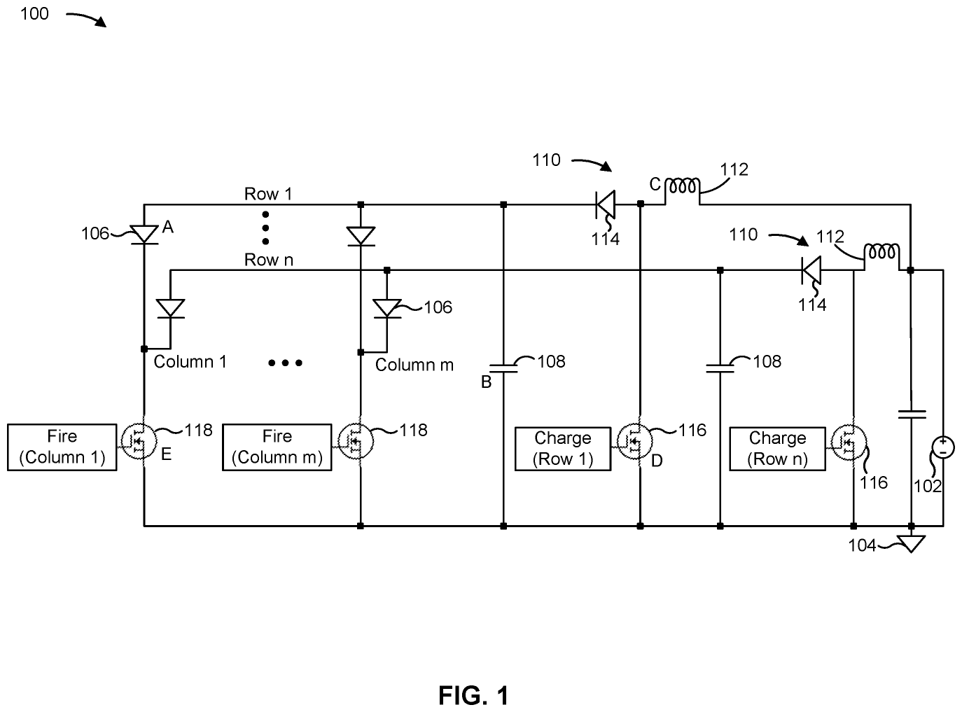

FIG. 1 is a diagram of an example driver circuit 100 described herein. The driver circuit 100 may include a source 102. The source 102 may provide an electrical input of the driver circuit 100. For example, the source 102 may provide current to the driver circuit 100. The source 102 may be a direct current (DC) voltage source, a DC current source with a resistive load, or the like. The driver circuit 100 may include a ground 104.

The driver circuit 100 may include an array of optical emitters 106. The array of optical emitters 106 may include a plurality of optical emitters 106. An optical emitter 106 may include a light-emitting diode (LED), a laser diode, a semiconductor laser diode, a VCSEL, and/or an edge-emitting emitter (e.g., an edge-emitting laser), among other examples. The array of optical emitters 106 may be arranged into one or more (e.g., a plurality of) rows (shown as Rows 1-n) and one or more (e.g., a plurality of) columns (shown as Columns 1-m). For example, n and m may be equal, n may be greater than m, or m may be greater than n. In some implementations, the array of optical emitters 106 is a two-dimensional array whereby the optical emitters 106 are arranged into a plurality of rows and a plurality of columns. For example, the array of optical emitters 106 may include 10 or more rows, 12 or more rows, 15 or more rows, etc., and 10 or more columns, 12 or more columns, 15 or more columns, etc. As an example, the array of optical emitters 106 may include 16 rows and 12 columns. In some implementations, the array of optical emitters 106 is a one-dimensional array whereby the optical emitters 106 are arranged into a single row (that includes a plurality of columns) or arranged into a single column (that includes a plurality of rows). For example, the array of optical emitters 106 may include a single column of optical emitters in a common cathode configuration. In an example used throughout the description of FIG. 1, the array of optical emitters 106 may include an optical emitter 106 A associated with Row 1 and Column 1 of the array of optical emitters 106.

The driver circuit 100 may include one or more (e.g., a plurality of) capacitive elements 108 (e.g., capacitive voltage sources). A capacitive element 108 may include a capacitor configured to store energy in response to current flowing through the capacitor, and configured to discharge the stored energy from the capacitor. In some implementations, a capacitive element 108 may include one or more capacitors. A capacitive element 108 may have an electrical capacitance in a range from about (e.g., ±1%) 1 nanofarad to 100 nanofarads.

Each row of the array of optical emitters 106 may be connected to (e.g., in a circuit path with) a respective capacitive element 108 (e.g., at an anode side of the array of optical emitters 106). For example, a capacitive element 108 B may be connected to Row 1. Thus, each capacitive element 108 operates as a voltage source for a particular row of the array of optical emitters 106. As shown, for an array that includes multiple rows of optical emitters 106, the driver circuit 100 may include multiple capacitive elements 108, and the multiple capacitive elements 108 may be respectively connected to the multiple rows.

In some implementations, a capacitive element 108 may be directly connected to the optical emitter(s) 106 (e.g., the anodes of the optical emitter(s) 106) of a row of the array of optical emitters 106. That is, the capacitive element 108 may be directly connected to the row. For example, no other circuit components may be in a circuit path between the capacitive element 108 and the optical emitter(s) 106 of the row.

The driver circuit 100 may include one or more (e.g., a plurality of) voltage booster elements 110 (e.g., configured to boost an input voltage). A voltage booster element 110 may include an inductive element 112. That is, the driver circuit 100 may include one or more (e.g., a plurality of) inductive elements 112. An inductive element 112 may include an inductor configured to store energy in response to current flowing through the inductor, and configured to discharge the stored energy from the inductor as current. In some implementations, an inductive element 112 may include one or more inductors. An inductive element 112 may have an electrical inductance in a range from about 0.5 nanohenry (nH) to 10 microhenry (μH).

Each voltage booster element 110 may be connected to (e.g., in a circuit path with) a respective capacitive element 108. For example, each inductive element 112 may be connected to (e.g., in a circuit path with) a respective capacitive element 108. As an example, an inductive element 112 C may be connected to Row 1. As shown, for an array that includes multiple rows of optical emitters 106 connected to multiple capacitive elements 108, the driver circuit 100 may include multiple voltage booster elements 110 (e.g., multiple inductive elements 112), and the multiple voltage booster elements 110 (e.g., multiple inductive elements 112) may be respectively connected to the multiple capacitive elements 108.

In some implementations, each voltage booster element 110 may include a diode 114 (e.g., a blocking diode). A diode 114 of the voltage booster element 110 may be in series between an inductive element 112 of the voltage booster element 110 and a capacitive element 108 to which the voltage booster element 110 is connected. The diode 114 ensures discharge of the capacitive element 108 along a desired circuit path. Thus, each inductive element 112 may be connected to a respective capacitive element 108 via a respective diode 114 (e.g., each inductive element 112 may be configured to discharge current to a respective capacitive element 108 through a respective diode 114). In this way, each voltage booster element 110 operates as a current source for a particular capacitive element 108.

The driver circuit 100 may include one or more (e.g., a plurality of) first switches 116 (which may be referred to herein as charging switches 116). Each inductive element 112 may be connected to (e.g., in a circuit path with) a respective charging switch 116. For example, a charging switch 116 D may be connected to the inductive element 112 C. As described below, a charging switch 116 may control charging of an inductive element 112 that is in the same circuit path as the charging switch 116. A charging switch 116 may be a field effect transistor (FET). For example, the FET may be a gallium nitride (GaN) FET, a complementary metal-oxide-semiconductor (CMOS) FET, or the like.

As shown, charging circuit paths of the driver circuit 100 may include the source 102, an inductive element 112, and a charging switch 116. For example, a first charging circuit path of the driver circuit 100 may include the source 102, a first inductive element 112, and a first charging switch 116; a second charging circuit path of the driver circuit 100 may include the source 102, a second inductive element 112, and a second charging switch 116; and so forth. As shown, for an array that includes multiple rows of optical emitters 106 connected to multiple capacitive elements 108, the driver circuit 100 may include multiple inductive elements 112 (e.g., respectively connected to the multiple capacitive elements 108) and multiple charging switches 116 respectively connected to the multiple inductive elements 112. Thus, the multiple charging switches 116 may control charging of respective inductive elements 112 of the multiple inductive elements 112.

A charging switch 116 may have a closed state (e.g., an on state) where, when the charging switch 116 is in the closed state, current may flow through the charging switch 116. Additionally, the charging switch 116 may have an open state (e.g., an off state), where, when the charging switch 116 is in the open state, current may not flow through the charging switch 116. The charging switch 116 may transition to the closed state in response to a “charge” signal (e.g., high voltage). The charging switch 116 may transition to the open state in response to a “discharge” signal (e.g., low voltage).

In the closed state, a charging switch 116 may cause current to charge an inductive element 112 connected to the charging switch 116 (e.g., by completing a circuit path that includes the source 102, the inductive element 112, and the charging switch 116). That is, when the charging switch 116 is in the closed state, current may flow through the charging switch 116 and charge the inductive element 112.

In some implementations, when the charging switch 116 is in the closed state, current may flow through the charging switch 116 and charge the inductive element 112 for a duration (e.g., a charging time interval). The duration may be in a range from 50 ns to 150 ns, 80 ns to 120 ns, 100 ns to 110 ns, or the like. Moreover, a duration for which a particular inductive element 112 is charged may be based on an optical pulse amplitude that is to be produced for a particular optical emitter 106 in the array (e.g., the duration may vary within the array). That is, the duration may be based on a current path length associated with the optical emitter 106 (e.g., a current path length from a capacitive element 108, connected to the optical emitter 106, to the optical emitter 106). Thus, each inductive element 112 may be charged for a respective duration (e.g., which may include charging multiple inductive elements 112 for the same duration and/or charging multiple inductive elements 112 for different durations, such as at least two different durations). In this way, by controlling the charging time intervals of the voltage booster elements 110, control (e.g., real-time control) of the current level at each optical emitter 106 in the array may be achieved.

When transitioning from the closed state to the open state, the charging switch 116 may cause the inductive element 112 to discharge current to a capacitive element 108 connected to the inductive element 112. That is, when the charging switch 116 is in the open state, current may not flow through the charging switch 116, and current discharges from the inductive element 112 to the capacitive element 108.

The driver circuit 100 may include one or more (e.g., a plurality of) second switches 118 (which may be referred to herein as discharging switches 118). Each column of the array of optical emitters 106 may be connected to (e.g., in a circuit path with) a respective discharging switch 118. For example, Column 1 may be connected to a discharging switch 118 E. As described below, a discharging switch 118 for a column may control selection of the column (e.g., by completing a cathode path of the column). A discharging switch 118 may be a FET (e.g., an n-type FET). For example, the FET may be a GaN FET, a CMOS FET, or the like. A discharging switch 118 may be a low side switch. In some implementations, a discharging switch 118 may be capable of operation in the closed state (e.g., capable of transitioning from the open state to the closed state, and subsequently transitioning from the closed state to the open state) for a time duration in a range from 0.5 ns to 10 ns. In some implementations, a discharging switch 118 may be a high-speed switch (e.g., may have a faster switching speed than a charging switch 116).

As shown, discharging circuit paths of the driver circuit 100 may include a capacitive element 108, an optical emitter 106, and a discharging switch 118. For example, a first discharging circuit path of the driver circuit 100 may include a first capacitive element 108 of a first row, an optical emitter 106 of the first row and a first column, and a first discharging switch 118 of the first column; a second discharging circuit path of the driver circuit 100 may include the first capacitive element 108 of the first row, an optical emitter 106 of the first row and a second column, and a second discharging switch 118 of the second column; and so forth. As shown, for an array that includes multiple columns of optical emitters 106, the driver circuit 100 may include multiple column switches 118 (e.g., respectively connected to the multiple columns) that control selection of respective columns of the multiple columns.

A discharging switch 118 may have a closed state (e.g., an on state) where, when the discharging switch 118 is in the closed state, current may flow through the discharging switch 118. Additionally, the discharging switch 118 may have an open state (e.g., an off state), where, when the discharging switch 118 is in the open state, current may not flow through the discharging switch 118. The discharging switch 118 may transition to the closed state in response to a “fire” signal (e.g., high voltage). The discharging switch 118 may transition to the open state in response to an “off” signal (e.g., low voltage).

Thus, in the closed state, a discharging switch 118 for a particular column may select the column. In particular, the discharging switch 118 in the closed state may cause discharging, of a charged capacitive element 108 of a row, through the row and the column, to provide an electrical pulse to an optical emitter 106 associated with the row and the column. For example, in the closed state, a discharging switch 118 for a particular column may close (e.g., complete) a cathode path of the column (e.g., current may flow through an optical emitter 106 in a column that has a discharging switch 118 in the closed state in a cathode path of the column). Stated differently, in the closed state, a discharging switch 118 for a particular column may complete a circuit path that includes the column. In the open state of a discharging switch 118 for a particular column, the column is no longer selected (e.g., by opening the cathode path of the column).

In some implementations, when a discharging switch 118 is in the closed state, current may flow through the discharging switch 118 and discharge a capacitive element 108 for a duration (e.g., a discharging time interval). The duration may be in a range from 1 ns to 10 ns, 1 ns to 5 ns, or the like. Moreover, a duration for which a particular capacitive element 108 is discharged may be based on an optical pulse width that is to be produced for a particular optical emitter 106 in the array (e.g., the duration may vary within the array). Thus, each capacitive element 108 may be discharged for a respective duration (e.g., which may include discharging multiple capacitive elements 108 for the same duration and/or discharging multiple capacitive elements 108 for different durations, such as at least two different durations). In this way, the pulse width may be controlled (e.g., in real time) based on a location of the optical emitter 106 in the array in order to equalize pulse widths across the array of optical emitters 106.

In an example operation of the driver circuit 100, the charging switch 116 D may transition from the open state to the closed state (e.g., in response to a “charge” signal) to cause current (e.g., from the source 102) to charge the inductive element 112 C (e.g., for a particular duration). Continuing with the example, the charging switch 116 D may transition from the closed state to the open state (e.g., in response to a “discharge” signal) to cause the inductive element 112 C to discharge current (e.g., through a diode 114) to the capacitive element 108 B to charge the capacitive element 108 B. Thereafter (e.g., after a voltage of the capacitive element 108 B stabilizes), the discharging switch 118 E may transition from the open state to the closed state (e.g., in response to a “fire” signal) to cause discharging of the capacitive element 108 B (e.g., a discharge of energy from the capacitive element 108 B) through Row 1 and Column 1 to provide an electrical pulse to the optical emitter 106 A. In response to the electrical pulse, the optical emitter 106 A may emit an optical pulse (e.g., having a duration in a range from 1 ns to 10 ns, 1 ns to 5 ns, or the like). As described above, an amplitude of the optical pulse may be controlled by a first duration for which the inductive element 112 C is charged (e.g., for which the charging switch 116 D is in the closed state), and a width of the optical pulse may be controlled by a second duration for which the discharging switch 118 E is in the closed state. In some implementations, the first duration and/or the second duration may be based on a current path length associated with the optical emitter 106 A (e.g., a current path length from the capacitive element 108 B to the optical emitter 106 A).

The driver circuit 100 is a high-speed driver circuit capable of generating optical pulses across a range of widths (in a time domain) and/or a range of powers (e.g., amplitudes). Moreover, the driver circuit 100 may be used to address different optical emitters 106 of the array of optical emitters 106. In some implementations, the driver circuit 100 may generate an optical pulse that is a Gaussian pulse. For example, the driver circuit 100 may be configured to operate in a resonant mode based on discharging of a capacitive element 108. Operation in the resonant mode may reduce the rise time of an electrical pulse. Moreover, by operating in the resonant mode, the driver circuit 100 may achieve peak currents for the electrical pulse using capacitive elements 108 that have a relatively small capacitance, thereby facilitating miniaturization of the driver circuit 100.

Capacitance values for the capacitive elements 108 may be selected to achieve a particular pulse width (e.g., from 1 ns to 10 ns) and/or to achieve discharging of the capacitive elements 108 to a voltage below a lasing threshold of the optical emitters 106 (e.g., so that after discharging a capacitive element 108 for pulsing an optical emitter 106, a capacitive element 108 can be charged for generating a pulse in a different optical emitter 106 associated with a different row or the same row but a different column).

In some implementations, a controller for the array of optical emitters 106 may include the driver circuit 100 or a portion thereof. For example, the controller may include a plurality of capacitive elements 108 respectively connected to the plurality of rows of the array of optical emitters 106, a plurality of inductive elements 112 respectively connected to the plurality of capacitive elements 108, and a plurality of first switches 116 (i.e., charging switches) respectively connected to the plurality of inductive elements 112. As described above, the plurality of charging switches 116 may each have an open state and a closed state. A charging switch 116, of the plurality of charging switches 116, in the closed state is to cause charging of an inductive element 112 of the plurality of inductive elements 112, and the charging switch 116 transitioning from the closed state to the open state is to cause discharging of the inductive element 112 to charge a capacitive element 108, of the plurality of capacitive elements 108, for a row of the plurality of rows. Additionally, the controller may include a plurality of second switches 118 (i.e., discharging switches) respectively connected to the plurality of columns of the array of optical emitters 106. As described above, the plurality of discharging switches 118 may each have an open state and a closed state. A discharging switch 118, of the plurality of discharging switches 118, connected to a column of the plurality of columns, in the closed state is to cause discharging of the capacitive element 108 through the row and the column.

In some implementations, an optical source may include the driver circuit 100 or a portion thereof and/or the controller, described above, or a portion thereof. In some implementations, an optical system may include the driver circuit 100 or a portion thereof and/or the controller, described above, or a portion thereof. Moreover, the optical system may include one or more lenses, one or more optical elements (e.g., diffractive optical elements, refractive optical elements, or the like), one or more reflector elements, and/or one or more optical sensors, among other examples.

In some implementations, the driver circuit 100 or a portion thereof and/or the controller, described above, or a portion thereof may be included in a ToF-based (e.g., direct ToF or indirect ToF) measurement system. For example, the ToF-based measurement system may include a LIDAR system. According to some implementations, a method may include generating an optical pulse for ToF-based measurement using the driver circuit 100 or a portion thereof and/or the controller, described above, or a portion thereof; and/or detecting an object based on the optical pulse. According to some implementations, a method may include generating (or forming) an array of light spots for three-dimensional sensing using the driver circuit 100 or a portion thereof and/or the controller, described above, or a portion thereof. According to some implementations, a method may include generating (or forming) a light pattern for three-dimensional sensing using driver circuit 100 or a portion thereof and/or the controller, described above, or a portion thereof.

As indicated above, FIG. 1 is provided as an example. Other examples may differ from what is described with regard to FIG. 1.

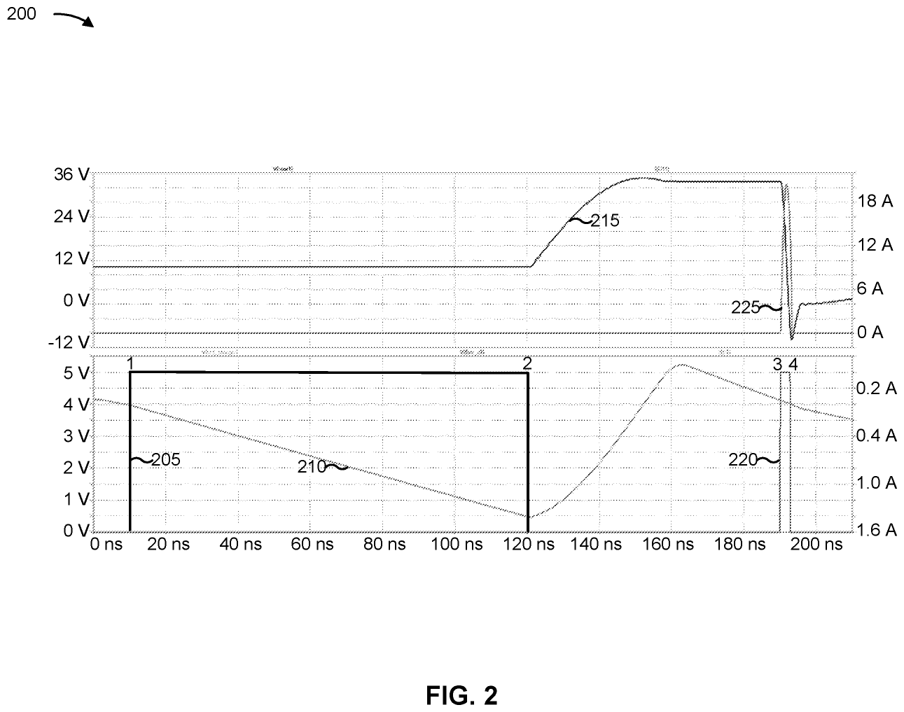

FIG. 2 is a diagram of an example graph 200 plotting electrical signals associated with an example driver circuit described herein. For example, the electrical signals of the graph 200 may be associated with the driver circuit 100, described above. The graph 200 shows the electrical signals associated with generating an optical pulse at an optical emitter of an array of optical emitters. That is, the optical emitter (e.g., optical emitter 106 A) may be associated with a row (e.g., Row 1) and a column (e.g., Column 1) of the array of optical emitters.

Line 205 shows a “charge” signal (high voltage). As described above, the “charge” signal causes a charging switch (e.g., a charging switch 116) to transition to the closed state (e.g., at a rising edge of line 205 at point 1). The “charge” signal may have a duration (e.g., from point 1 to point 2 of line 205) in a range from 10 ns to 120 ns, such as 110 ns. As described above, the duration may be based on a desired optical pulse amplitude for the optical emitter, and may vary within the array of the optical emitters. Closing the charging switch, in response to the “charge” signal, may cause current to charge the inductive element (e.g., an inductive element 112), as shown by line 210.

As further shown by line 205, a “discharge” signal (low voltage) causes the charging switch to transition from the closed state to the open state (e.g., at a falling edge of line 205 at point 2). Opening of the charging switch, in response to the “discharge” signal, may cause current to discharge from the inductive element (e.g., through a blocking diode, such as a diode 114) to a capacitive element (e.g., a capacitive element 108) connected to the row (e.g., Row 1) of the array of optical emitters. As shown by line 215, discharging the inductive element causes a voltage on the capacitive element to rise (e.g., to about 34 volts (V), as shown). When the voltage stabilizes, a current pulse can be generated at the optical emitter.

Line 220 shows a “fire” signal (high voltage). As described above, the “fire” signal causes a discharging switch (e.g., a discharging switch 118) to transition to the closed state (e.g., at a rising edge of line 220 at point 3). The “fire” signal may have a duration (e.g., from point 3 to point 4 of line 220) in a range from 1 ns to 10 ns, such as 5 ns. As described above, the duration may be based on a desired optical pulse width for the optical emitter. In some implementations, the duration of the “fire” signal may be longer than the desired optical pulse width (e.g., about 2-3 ns longer).

Closing of the discharging switch, in response to the “fire” signal, may cause discharging of the capacitive element. The capacitive element discharges through the row and through the column (e.g., through a circuit path that includes the optical emitter associated with the row and the column) due to the discharging switch being closed. Discharging of the capacitive element provides an electrical pulse, shown by line 225, at the optical emitter associated with the row and the column. The electrical pulse generates an optical pulse at the optical emitter. A duration of the electrical pulse/optical pulse (e.g., a duration in a range from 1 ns to 10 ns) may correspond to a duration for which the discharging switch is closed.

As indicated above, FIG. 2 is provided as an example. Other examples may differ from what is described with regard to FIG. 2.

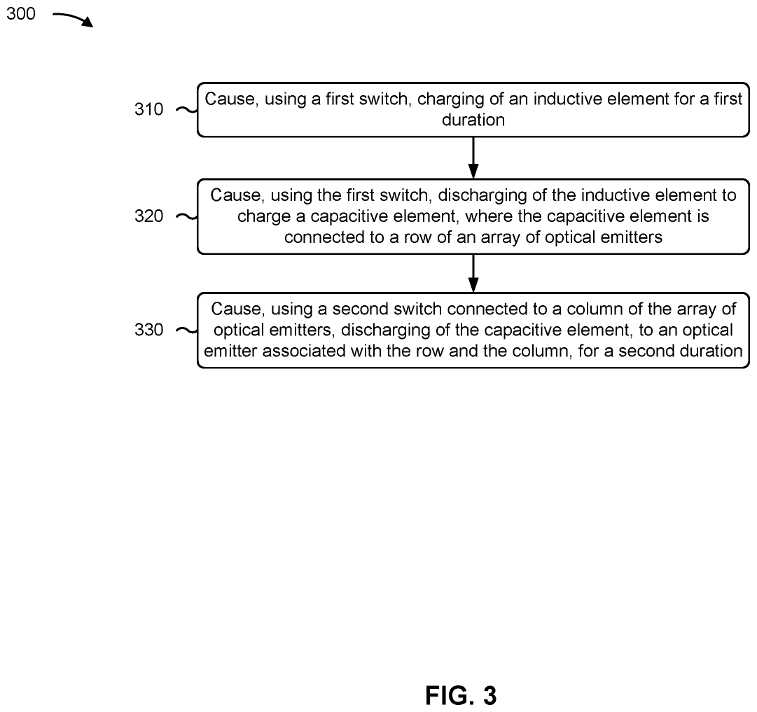

FIG. 3 is a flowchart of an example process 300 associated with controlling a driver circuit for an addressable array of optical emitters described herein. For example, the process 300 may relate to the driver circuit 100, described above. In some implementations, one or more process blocks of FIG. 3 may be performed by a device, such as a controller external to the driver circuit. For example, the controller may provide the “charge” signal, the “discharge” signal, the “fire” signal, and/or the “off” signal, as described above, to the driver circuit.

As shown in FIG. 3, process 300 may include causing, using a first switch (i.e., a charging switch), charging of an inductive element for a first duration (block 310). For example, the device may cause, using a first switch (e.g., a charging switch 116), charging of an inductive element (e.g., an inductive element 112) for a first duration, as described above. As an example, the device may provide a “charge” signal to the first switch to cause charging of the inductive element.

As further shown in FIG. 3, process 300 may include causing, using the first switch, discharging of the inductive element to charge a capacitive element, where the capacitive element is connected to a row of an array of optical emitters (block 320). For example, the device may cause, using the first switch, discharging of the inductive element to charge a capacitive element. As an example, the device may provide a “discharge” signal to the first switch to cause discharging of the inductive element to charge the capacitive element (e.g., a capacitive element 108). In some implementations, the capacitive element is connected to a row of an array of optical emitters (e.g., the array of optical emitters 106).

As further shown in FIG. 3, process 300 may include causing, using a second switch (i.e., a discharging switch) connected to a column of the array of optical emitters, discharging of the capacitive element, to an optical emitter associated with the row and the column, for a second duration (block 330). For example, the device may cause, using a second switch (e.g., a discharging switch 118) connected to a column of the array of optical emitters, discharging of the capacitive element, to an optical emitter (e.g., an optical emitter 106) associated with the row and the column, for a second duration, as described above. As an example, the device may provide a “fire” signal to the second switch to cause discharging of the capacitive element.

As described above, the first duration may be based on an optical pulse amplitude that is to be produced for the optical emitter. Because the optical pulse amplitude may be affected by a parasitic inductance associated with optical emitter, the first duration (e.g., to produce a particular optical pulse amplitude) may be based on a location of the optical emitter in the array of optical emitters. For example, the first duration may be based on a current path length associated with the optical emitter (e.g., a current path length from the capacitive element to the optical emitter). In some implementations, the device may store information identifying respective current path lengths for the optical emitters of the array, and the device may use the information to determine respective first durations for which a plurality of inductive elements are to be charged. Additionally, or alternatively, the first duration may be based on a return signal, associated with the optical emitter, received at the device. For example, the return signal may be a reflection of a signal of the optical emitter and, therefore, a power of the return signal may indicate a power of the signal. Thus, the return signal may indicate whether an optical pulse amplitude of the emitter should be higher, lower, or maintained. In some implementations, the device may determine respective first durations for which the plurality of inductive elements are to be charged based on respective return signals associated with the array of optical emitters.

As described above, the second duration may be based on an optical pulse width that is to be produced for the optical emitter. In some implementations, the second duration (e.g., to produce a particular optical pulse width) may be based on a location of the optical emitter in the array of optical emitters (e.g., based on information identifying respective current path lengths and/or based on return signals), in a similar manner as described above.

In some implementations, the first duration may be different from a duration for charging another inductive element configured to discharge to another capacitive element connected to another row of the array of optical emitters. In other words, each inductive element may be charged for a duration that is specific to an optical emitter of the array that is to be pulsed, as described above. In some implementations, the second duration may be different from a duration used by another discharging switch for pulsing another optical emitter associated with another column of the array of optical emitters. In other words, each discharging switch may be closed for a duration that is specific to an optical emitter of the array that is to be pulsed, as described above. In some implementations, at least one of the first duration or the second duration is different from a duration used for a causing a previous optical pulse of the optical emitter or another optical emitter. In other words, a particular inductive element may be charged for different durations from pulse to pulse, or a particular discharge switch may be closed for different durations from pulse to pulse. In this way, real-time control of optical emitters of the array may be achieved.

Although FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

The foregoing disclosure provides illustration and description, but is not intended to be exhaustive or to limit the implementations to the precise forms disclosed. Modifications and variations may be made in light of the above disclosure or may be acquired from practice of the implementations. Furthermore, any of the implementations described herein may be combined unless the foregoing disclosure expressly provides a reason that one or more implementations may not be combined.

Even though particular combinations of features are recited in the claims and/or disclosed in the specification, these combinations are not intended to limit the disclosure of various implementations. In fact, many of these features may be combined in ways not specifically recited in the claims and/or disclosed in the specification. Although each dependent claim listed below may directly depend on only one claim, the disclosure of various implementations includes each dependent claim in combination with every other claim in the claim set. As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiple of the same item.

No element, act, or instruction used herein should be construed as critical or essential unless explicitly described as such. Also, as used herein, the articles “a” and “an” are intended to include one or more items, and may be used interchangeably with “one or more.” Further, as used herein, the article “the” is intended to include one or more items referenced in connection with the article “the” and may be used interchangeably with “the one or more.” Furthermore, as used herein, the term “set” is intended to include one or more items (e.g., related items, unrelated items, or a combination of related and unrelated items), and may be used interchangeably with “one or more.” Where only one item is intended, the phrase “only one” or similar language is used. Also, as used herein, the terms “has,” “have,” “having,” or the like are intended to be open-ended terms. Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A driver circuit, comprising:
an array of optical emitters arranged in one or more rows and one or more columns,
wherein the array of optical emitters includes an optical emitter associated with a row of the one or more rows and a column of the one or more columns;
a capacitive element connected to the row;
a voltage booster element connected to the capacitive element,
wherein the voltage booster element includes an inductive element;
a first switch having an open state and a closed state,
wherein the first switch in the closed state is to cause charging of the inductive element, and
wherein the first switch transitioning from the closed state to the open state is to cause discharging of the inductive element to charge the capacitive element; and
a second switch having an open state and a closed state,
wherein the second switch in the closed state is to select the column, and
wherein the second switch in the closed state is to cause discharging of the capacitive element through the row and the column to provide an electrical pulse to the optical emitter associated with the row and the column.

2. The driver circuit of claim 1, wherein the voltage booster element further includes a blocking diode between the capacitive element and the inductive element.

3. The driver circuit of claim 1, wherein the array of optical emitters is arranged in multiple rows, and
wherein the inductive element is one of multiple inductive elements, the first switch is one of multiple first switches respectively connected to the multiple inductive elements, and the capacitive element is one of multiple capacitive elements respectively connected to the multiple rows and the multiple inductive elements.

4. The driver circuit of claim 3, wherein the multiple first switches control charging of respective inductive elements of the multiple inductive elements.

5. The driver circuit of claim 1, wherein the array of optical emitters is arranged in multiple columns, and
wherein the second switch is one of multiple second switches respectively connected to the multiple columns.

6. The driver circuit of claim 5, wherein the multiple second switches control selection of respective columns of the multiple columns.

7. The driver circuit of claim 1, wherein the first switch in the closed state is to cause charging of the inductive element for a duration that is based on an optical pulse amplitude that is to be produced for the optical emitter.

8. The driver circuit of claim 7, wherein the duration is based on a current path length associated with the optical emitter.

9. The driver circuit of claim 1, wherein the second switch in the closed state is to cause discharging of the capacitive element for a duration that is based on an optical pulse width that is to be produced for the optical emitter.

10. A controller for an array of optical emitters arranged in a plurality of rows and a plurality of columns, comprising:
a plurality of capacitive elements respectively connected to the plurality of rows;
a plurality of inductive elements respectively connected to the plurality of capacitive elements;
a plurality of first switches respectively connected to the plurality of inductive elements,
wherein the plurality of first switches have an open state and a closed state,
wherein a first switch, of the plurality of first switches, in the closed state is to cause charging of an inductive element of the plurality of inductive elements, and
wherein the first switch transitioning from the closed state to the open state is to cause discharging of the inductive element to charge a capacitive element, of the plurality of capacitive elements, for a row of the plurality of rows; and
a plurality of second switches respectively connected to the plurality of columns,
wherein the plurality of second switches have an open state and a closed state, and
wherein a second switch, of the plurality of second switches, connected to a column of the plurality of columns, in the closed state is to cause discharging of the capacitive element through the row and the column.

11. The controller of claim 10, wherein the plurality of inductive elements are included in respective voltage booster elements, and
wherein the respective voltage booster elements also include respective blocking diodes.

12. The controller of claim 11, wherein the respective blocking diodes are in series between the plurality of capacitive elements and the plurality of inductive elements.

13. The controller of claim 10, wherein the plurality of first switches, in the closed state, are to cause charging of the plurality of inductive elements for at least two different durations.

14. The controller of claim 10, wherein the plurality of second switches, in the closed state, are to cause discharging of the plurality of capacitive elements for at least two different durations.

15. A method, comprising:
causing, by a device and using a first switch, charging of an inductive element for a first duration;
causing, by the device and using the first switch, discharging of the inductive element to charge a capacitive element,
wherein the capacitive element is connected to a row of an array of optical emitters; and
causing, by the device and using a second switch connected to a column of the array of optical emitters, discharging of the capacitive element, to an optical emitter associated with the row and the column, for a second duration.

16. The method of claim 15, wherein the first duration is based on a location of the optical emitter in the array of optical emitters.

17. The method of claim 15, wherein the first duration is based on a return signal, associated with the optical emitter, received at the device.

18. The method of claim 15, wherein the first duration is different from a duration for charging another inductive element configured to discharge to another capacitive element connected to another row of the array of optical emitters.

19. The method of claim 15, wherein the first duration is based on an optical pulse amplitude that is to be produced for the optical emitter.

20. The method of claim 15, wherein the second duration is based on an optical pulse width that is to be produced for the optical emitter.
